(19) United States
(12) Patent Application Publication
(10) Pub. No.: US 2026/0277121 A1
(43) Pub. Date: Sep. 17, 2026

(54) METHOD FOR CONFIGURING A FIELD OF VIEW OF AN INSPECTION APPARATUS

(71) Applicant: ASML NETHERLANDS B.V., Veldhoven (NL)

(72) Inventors: Vahid BASTANI, Eindhoven (NL); Konstantin Sergeevich NECHAEV, Veldhoven (NL); Roy ANUNCIADO, Eindhoven (NL); Stefan Cornelis Theodorus VAN DER SANDEN, Nijmegen (NL)

(73) Assignee: ASML NETHERLANDS B.V., Veldhoven (NL)

(21) Appl. No.: 18/873,850

(22) PCT Filed: Aug. 2, 2023
(86) PCT No.: PCT/EP2023/071406

§ 371 Date: Dec. 11, 2024

(30) Foreign Application Priority Data
Sep. 2, 2022 (EP) 22193741.0

(51) Int. Cl. G03F 7/00; G01B 11/02

(52) U.S. Cl. CPC G03F 7/706845; G01B 11/02; G03F 7/70625; G03F 7/706837; G03F 7/706839; G03F 7/706851

(57) ABSTRACT

A method for configuring a field of view configuration of an inspection apparatus with respect to a pattern on a patterned substrate to be measured. The method includes: obtaining metrology data including at least one parameter distribution across at least a portion of the pattern, the at least one parameter distribution relating to a respective one or more parameters of interest and/or respective one or more proxy parameters for a parameter of interest; determining variation metric data quantifying an amount of variation captured within the parameter distribution when limited to the field of view for varied field of view configurations; and configuring the field of view configuration with respect to the pattern based on the variation metric data.

### CROSS-REFERENCE TO RELATED APPLICATIONS

This application claims priority of EP Application Serial No. 22193741.0 which was filed on Sep. 2, 2022 and which is incorporated herein in its entirety by reference.

### FIELD

The present invention relates to methods and apparatus for applying patterns to a substrate in a lithographic process, and more specifically inspection of such patterns once applied.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In order to monitor the lithographic process, parameters of the patterned substrate are measured. Parameters may include, for example, the overlay error between successive layers formed in or on the patterned substrate and critical linewidth or critical dimension (CD) of developed photosensitive resist. This measurement may be performed on a product substrate and/or on a dedicated metrology target. There are various techniques for making measurements of the microscopic structures formed in lithographic processes, including the use of scanning electron microscopes and various specialized tools.

In performing lithographic processes, such as application of a pattern on a substrate or measurement of such a pattern, process control methods are used to monitor and control the process. Such process control techniques are typically performed to obtain corrections for control of the lithographic process. It would be desirable to improve such process control methods.

Such process control methods typically rely on inspection or metrology of exposed patterns, e.g., using a scanning electron microscope. When the pattern being exposed is irregular, such as for logic circuits, there is a large variety of different feature types which cannot all be measured in a practical commercial setting. As such, a method of configuring an inspection apparatus is desirable.

### SUMMARY

In a first aspect of the invention there is provided a method for configuring a field of view configuration of an inspection apparatus with respect to a pattern on a patterned substrate to be measured, the method comprising: obtaining metrology data comprising at least one parameter distribution across at least a portion of the pattern, said at least one parameter distribution relating to a respective one or more parameters of interest and/or respective one or more proxy parameters for a parameter of interest; determining a variation metric from the metrology data, the variation metric quantifying an amount of variation captured within the parameter distribution when limited to a field of view, for varied field of view configurations; and configuring the field of view configuration with respect to the pattern based on said variation metric.

In a second aspect of the invention, there is provided a computing apparatus comprising a processor, and being configured to perform the method of the first aspect.

In a third aspect of the invention, there is provided an inspection apparatus being operable to image a plurality of features on a substrate, and comprising the computing apparatus of the second aspect.

In a fourth aspect of the invention, there is provided a computer program comprising program instructions operable to perform the method of the first aspect when run on a suitable apparatus.

Further aspects, features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example, with reference to the accompanying drawings in which:

FIG. 1 depicts a lithographic apparatus together with other apparatuses forming a production facility for semiconductor devices;

FIG. 2 is a flow diagram of simulation models corresponding to the subsystems of a lithographic apparatus;

FIG. 3 schematically depicts two examples of stochastic variation: (a) line edge roughness LER; and (b) schematically line width roughness (LWR);

FIG. 4 shows a graph of dose E against position x, illustrating the concept of a blurred ILS;

FIG. 5 is a flow diagram of a method of determining a relationship between a stochastic variation of a characteristic of an aerial image or a resist image and one or more design variables;

FIG. 6 is a flowchart of a method for calculating and illustrating the stochastic variation; and

FIG. 7 is a flowchart of a method according to an embodiment of the invention.

### DETAILED DESCRIPTION

Before describing embodiments of the invention in detail, it is instructive to present an example environment in which embodiments of the present invention may be implemented.

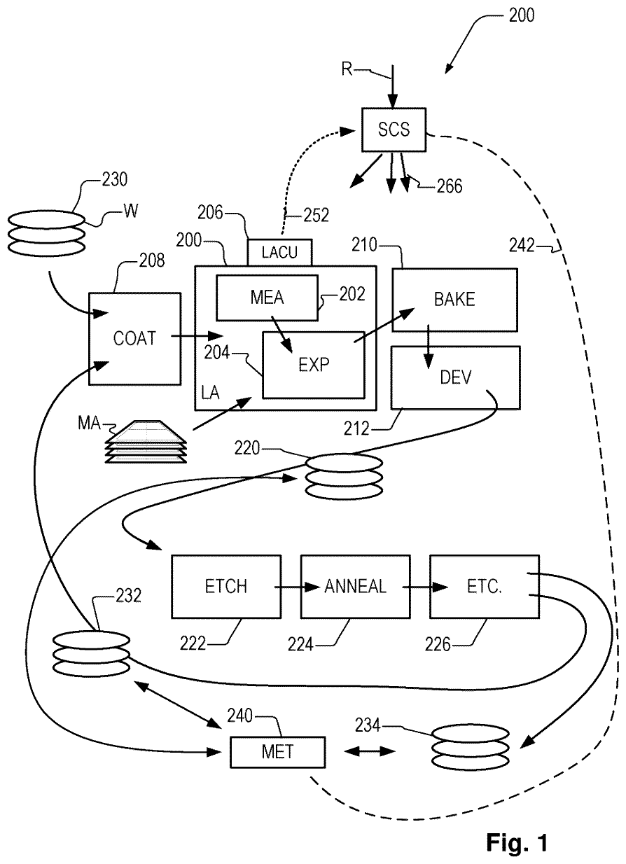

FIG. 1 at 200 shows a lithographic apparatus LA as part of an industrial production facility implementing a high-volume, lithographic manufacturing process. In the present example, the manufacturing process is adapted for the manufacture of for semiconductor products (integrated circuits) on substrates such as semiconductor wafers. The skilled person will appreciate that a wide variety of products can be manufactured by processing different types of substrates in variants of this process. The production of semiconductor products is used purely as an example which has great commercial significance today.

Within the lithographic apparatus (or “litho tool” 200 for short), a measurement station MEA is shown at 202 and an exposure station EXP is shown at 204. A control unit LACU is shown at 206. In this example, each substrate visits the measurement station and the exposure station to have a pattern applied. In an optical lithographic apparatus, for example, a projection system is used to transfer a product pattern from a patterning device MA onto the substrate using conditioned radiation and a projection system. This is done by forming an image of the pattern in a layer of radiation-sensitive resist material.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. The patterning MA device may be a mask or reticle, which imparts a pattern to a radiation beam transmitted or reflected by the patterning device. Well-known modes of operation include a stepping mode and a scanning mode. As is well known, the projection system may cooperate with support and positioning systems for the substrate and the patterning device in a variety of ways to apply a desired pattern to many target portions across a substrate. Programmable patterning devices may be used instead of reticles having a fixed pattern. The radiation for example may include electromagnetic radiation in the deep ultraviolet (DUV) or extreme ultraviolet (EUV) wavebands. The present disclosure is also applicable to other types of lithographic process, for example imprint lithography and direct writing lithography, for example by electron beam.

The lithographic apparatus control unit LACU which controls all the movements and measurements of various actuators and sensors to receive substrates W and reticles MA and to implement the patterning operations. LACU also includes signal processing and data processing capacity to implement desired calculations relevant to the operation of the apparatus. In practice, control unit LACU will be realized as a system of many sub-units, each handling the real-time data acquisition, processing and control of a subsystem or component within the apparatus.

Before the pattern is applied to a substrate at the exposure station EXP, the substrate is processed in at the measurement station MEA so that various preparatory steps may be carried out. The preparatory steps may include mapping the surface height of the substrate using a level sensor and measuring the position of alignment marks on the substrate using an alignment sensor. The alignment marks are arranged nominally in a regular grid pattern. However, due to inaccuracies in creating the marks and also due to deformations of the substrate that occur throughout its processing, the marks deviate from the ideal grid. Consequently, in addition to measuring position and orientation of the substrate, the alignment sensor in practice must measure in detail the positions of many marks across the substrate area, if the apparatus is to print product features at the correct locations with very high accuracy. The apparatus may be of a so-called dual stage type which has two substrate tables, each with a positioning system controlled by the control unit LACU. While one substrate on one substrate table is being exposed at the exposure station EXP, another substrate can be loaded onto the other substrate table at the measurement station MEA so that various preparatory steps may be carried out. The measurement of alignment marks is therefore very time-consuming and the provision of two substrate tables enables a substantial increase in the throughput of the apparatus. If the position sensor IF is not capable of measuring the position of the substrate table while it is at the measurement station as well as at the exposure station, a second position sensor may be provided to enable the positions of the substrate table to be tracked at both stations. Lithographic apparatus LA may for example is of a so-called dual stage type which has two substrate tables and two stations—an exposure station and a measurement station-between which the substrate tables can be exchanged.

Within the production facility, apparatus 200 forms part of a “litho cell” or “litho cluster” that contains also a coating apparatus 208 for applying photosensitive resist and other coatings to substrates W for patterning by the apparatus 200. At an output side of apparatus 200, a baking apparatus 210 and developing apparatus 212 are provided for developing the exposed pattern into a physical resist pattern. Between all of these apparatuses, substrate handling systems take care of supporting the substrates and transferring them from one piece of apparatus to the next. These apparatuses, which are often collectively referred to as the track, are under the control of a track control unit which is itself controlled by a supervisory control system SCS, which also controls the lithographic apparatus via lithographic apparatus control unit LACU. Thus, the different apparatus can be operated to maximize throughput and processing efficiency. Supervisory control system SCS receives recipe information R which provides in great detail a definition of the steps to be performed to create each patterned substrate.

Once the pattern has been applied and developed in the litho cell, patterned substrates 220 are transferred to other processing apparatuses such as are illustrated at 222, 224, 226. A wide range of processing steps is implemented by various apparatuses in a typical manufacturing facility. For the sake of example, apparatus 222 in this embodiment is an etching station, and apparatus 224 performs a post-etch annealing step. Further physical and/or chemical processing steps are applied in further apparatuses, 226, etc., Numerous types of operation can be required to make a real device, such as deposition of material, modification of surface material characteristics (oxidation, doping, ion implantation etc.), chemical-mechanical polishing (CMP), and so forth. The apparatus 226 may, in practice, represent a series of different processing steps performed in one or more apparatuses. As another example, apparatus and processing steps may be provided for the implementation of self-aligned multiple patterning, to produce multiple smaller features based on a precursor pattern laid down by the lithographic apparatus.

As is well known, the manufacture of semiconductor devices involves many repetitions of such processing, to build up device structures with appropriate materials and patterns, layer-by-layer on the substrate. Accordingly, substrates 230 arriving at the litho cluster may be newly prepared substrates, or they may be substrates that have been processed previously in this cluster or in another apparatus entirely. Similarly, depending on the required processing, substrates 232 on leaving apparatus 226 May be returned for a subsequent patterning operation in the same litho cluster, they may be destined for patterning operations in a different cluster, or they may be finished products to be sent for dicing and packaging.

Each layer of the product structure requires a different set of process steps, and the apparatuses 226 used at each layer may be completely different in type. Further, even where the processing steps to be applied by the apparatus 226 are nominally the same, in a large facility, there may be several supposedly identical machines working in parallel to perform the step 226 on different substrates. Small differences in set-up or faults between these machines can mean that they influence different substrates in different ways. Even steps that are relatively common to each layer, such as etching (apparatus 222) may be implemented by several etching apparatuses that are nominally identical but working in parallel to maximize throughput. In practice, moreover, different layers require different etch processes, for example chemical etches, plasma etches, according to the details of the material to be etched, and special requirements such as, for example, anisotropic etching.

The previous and/or subsequent processes may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which litho cell LC is located also includes metrology system which receives some or all of the substrates W that have been processed in the litho cell. Metrology results are provided directly or indirectly to the supervisory control system SCS. If errors are detected, adjustments may be made to exposures of subsequent substrates, especially if the metrology can be done soon and fast enough that other substrates of the same batch are still to be exposed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

Also shown in FIG. 1 is a metrology apparatus 240 which is provided for making measurements of parameters of the products at desired stages in the manufacturing process. A common example of a metrology station in a modern lithographic production facility is a scatterometer, for example a dark-field scatterometer, an angle-resolved scatterometer or a spectroscopic scatterometer, and it may be applied to measure properties of the developed substrates at 220 prior to etching in the apparatus 222. Using metrology apparatus 240, it may be determined, for example, that important performance parameters such as overlay or critical dimension (CD) do not meet specified accuracy requirements in the developed resist. Prior to the etching step, the opportunity exists to strip the developed resist and reprocess the substrates 220 through the litho cluster. The metrology results 242 from the apparatus 240 can be used to maintain accurate performance of the patterning operations in the litho cluster, by supervisory control system SCS and/or control unit LACU 206 making small adjustments over time, thereby minimizing the risk of products being made out-of-specification, and requiring re-work.

Another example of a metrology station is a scanning electron microscope (SEM), otherwise referred to as an electron beam (e-beam) metrology device, which may be included in addition to, or as an alternative to, a scatterometer. As such, metrology apparatus 240 may comprise an e-beam or SEM metrology device, either alone or in addition to a scatterometer. E-beam and SEM metrology devices have the advantage of measuring features directly (i.e., they directly image the features), rather than the indirect measurement techniques used in scatterometry (where parameter values are determined from reconstruction from and/or asymmetry in diffraction orders of radiation diffracted by the structure being measured). The main disadvantage with e-beam or SEM metrology devices is their measurement speed, which is much slower than scatterometry, limiting their potential application to specific offline monitoring processes.

Additionally, metrology apparatus 240 and/or other metrology apparatuses (not shown) can be applied to measure properties of the processed substrates 232, 234, and incoming substrates 230. The metrology apparatus can be used on the processed substrate to determine important parameters such as overlay or CD.

Lithographic projection apparatuses typically project a patterned (i.e., by a reticle) image at a point immediately above the substrate, and then ultimately into the resist. The projected image is called the aerial image, which comprises a distribution of light intensity as a function of spatial position in the image plane. The aerial image is the source of the information that is exposed into the resist, forming a gradient in dissolution rates that enables the three-dimensional resist image to appear during development.

In a lithographic projection apparatus, a source provides illumination (i.e. radiation) to a patterning device and projection optics direct and shape the illumination, via the patterning device, onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the source and the projection optics.

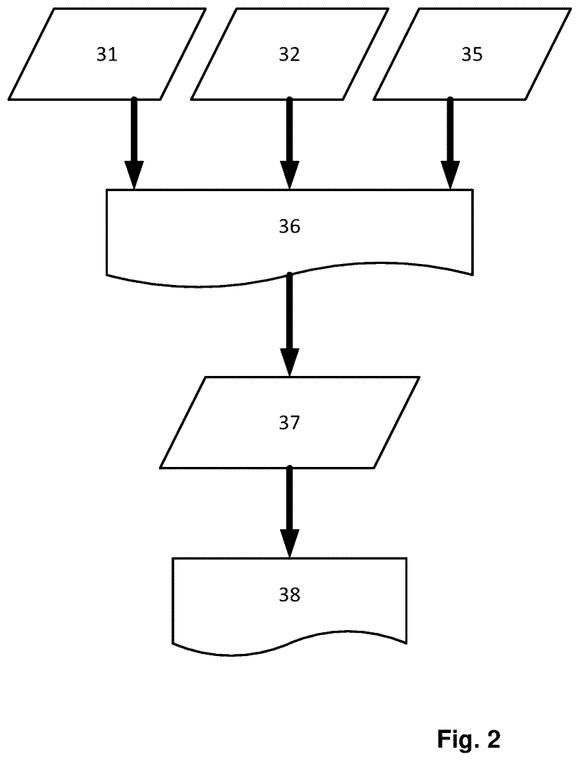

FIG. 2 is an exemplary flow chart for simulating lithography in a lithographic projection apparatus. A source model 31 represents optical characteristics (including radiation intensity distribution and/or phase distribution) of the source. A projection optics model 32 represents optical characteristics (including changes to the radiation intensity distribution and/or the phase distribution caused by the projection optics) of the projection optics. A design layout model 35 represents optical characteristics (including changes to the radiation intensity distribution and/or the phase distribution caused by a given design layout 33) of a design layout, which is the representation of an arrangement of features on or formed by a patterning device. An aerial image 36 can be simulated from the design layout model 35, the projection optics model 32 and the design layout model 35. A resist image 38 can be simulated from the aerial image 36 using a resist model 37. Simulation of lithography can, for example, predict contours and CDs in the resist image.

More specifically, it is noted that the source model 31 can represent the optical characteristics of the source that include, but not limited to, NA settings, sigma(s) settings as well as any particular illumination shape (e.g. off-axis radiation sources such as annular, quadrupole, dipole, etc.). The projection optics model 32 can represent the optical characteristics of the projection optics, including aberration, distortion, one or more refractive indexes, one or more physical sizes, one or more physical dimensions, etc. The design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an example, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization.

Alternatively, in another example, an initial larger set of clips may be extracted from the entire design layout by using some kind of automated (such as machine vision) or manual algorithm that identifies the one or more critical feature areas.

Stochastic induced failure predictions are typically made based on measurement of the variation of a dimensional parameter, such as CD (so called Local CD Uniformity, LCDU), line edge position (so called line edge roughness LER), or linewidth (so called linewidth roughness LWR), for example. Accurate measurement of the number of failures is cumbersome, as low failure rates (e.g., of the order of 1 per million to 1 per billion) can be expected in an optimized process. Therefore, failure predictions are based on stochastic LCDU, LER or LWR predictions which rely on relatively few measurements. In particular, it is known that stochastics are driven by optical contrast and more specifically, the image log slope (ILS). The ILS is the gradient of the logarithm of the aerial image intensity I:

$$ILS = \frac{1}{I} \frac{dI}{dx} = \frac{dlnI}{dx}$$

Since variations in the resist edge positions (linewidths) are typically expressed as a percentage of the nominal linewidth, the position coordinate x can be normalized by multiplying the ILS by the nominal linewidth w to obtain what is referred to as the normalized ILS, NILS:

$$NILS = \frac{dlnI}{dx} w$$

The concept of using an ILS for stochastic induced failure predictions is known. Such concepts can be found described in, for example, PCT patent publications WO2015/121127 and WO2016/128392, the contents of which are incorporated herein in their entirety.

Stochasticity is of greater importance for extreme ultraviolet (EUV) lithography, as features are smaller relative to lithography techniques using lower energy exposure radiation, as is the number of photons in the exposure radiation (because of their higher energy). EUV radiation is electromagnetic radiation having a wavelength within the range of 5-20 nm; for example within the range of 13-14 nm. It has further been proposed that EUV radiation with a wavelength of less than 10 nm could be used, for example within the range of 5-10 nm (e.g., 6.7 nm or 6.8 nm). Such radiation is termed extreme ultraviolet radiation or soft x-ray radiation. Possible sources for EUV radiation include, for example, laser-produced plasma sources, discharge plasma sources, or sources based on synchrotron radiation provided by an electron storage ring.

Imaging, using a lithographic projection apparatus, will result in a stochastic variation in one or more parameters, such as pronounced line width roughness (LWR) and local CD variation in small two-dimensional features such as holes. The stochastic variation may be attributed to factors such as photon shot noise, photon-generated secondary electrons, photon absorption variation, photon-generated acids in the resist. In the case of EUV lithography, the small sizes of features for which EUV is called for further compound this stochastic variation. The stochastic variation in smaller features are a significant factor in production yield and justifies inclusion in a variety of optimization processes of the lithographic projection apparatus.

Under the same radiation intensity, lower exposure time of each substrate leads to higher throughput of a lithographic projection apparatus but stronger stochastic effect. The photon shot noise in a given feature under a given radiation intensity is proportional to the square root of the exposure time. The desire to lower exposure time for the purpose of increasing the throughput exists in lithography using EUV and other radiation sources. Therefore, the methods and apparatuses described herein that consider the stochastic effect in the optimization process are not limited to EUV lithography.

The throughput can also be affected by the total amount of light directed to the substrate. In some lithographic projection apparatuses, a portion of the light (e.g., pupil fill ratio) from the source is sacrificed in order to achieve desired shapes of the source. Typically, a higher (N) ILS is obtained if the pupil fill ratio is lower, and as such there is a trade-off.

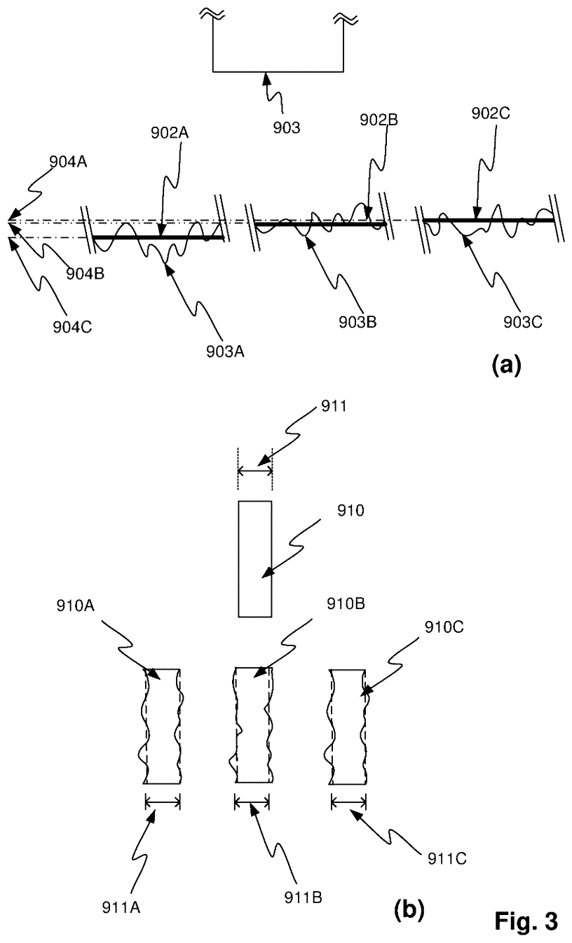

FIG. 3(a) schematically depicts a stochastic effect, line edge roughness LER. Assuming all conditions are identical in three exposures or simulations of exposure of an edge 903 of a feature on a design layout, the resist images 903A, 903B and 903C of the edge 903 may have slightly different shapes and locations. Locations 904A, 904B and 904C of the resist images 903 A, 903B and 903C may be measured by averaging the resist images 903A, 903B and 903C to obtain effective (averaged) edge positions 902A, 902B and 902C, respectively. LER of the edge 903 may be a measure of the spatial distribution of the locations 904A, 904B and 904C. For example, the LER may be a 30 of the spatial distribution (assuming the distribution is a normal distribution). The LER may be derived from many exposures or simulation of the edge 903.

FIG. 3(b) schematically depicts LWR. Assuming all conditions are identical in three exposures or simulations of exposure of a long rectangle feature 910 with a width 911 on a design layout, the resist images 910A, 910B and 910C of the rectangle feature 910 may have slightly different widths 911A, 911B and 911C, respectively. LWR of the rectangle feature 910 may be a measure of the distribution of the widths 911A, 911B and 911C. For example, the LWR may be a 30 of the distribution (assuming the distribution is a normal distribution). The LWR may be derived from many exposures or simulation of the rectangle feature 910. In the context of a short feature (e.g., a contact hole), the widths of its images are not well defined because long edges are not available for averaging their locations. A similar quantity, LCDU, may be used to characterize the stochastic variation. The LCDU is a 30 of the distribution (assuming the distribution is a normal distribution) of measured CDs of images of the short feature.

The essence of stochastics relates to the absorbed dose, which fluctuates due to the limited number of (absorbed) photons. This is practically reflected in CD variations from feature of feature and/or over the length of a feature. As such, stochastic variation as described herein may comprise a measure of the variation of any dimensional parameter, and as such may comprise a line edge roughness (LER), a line width roughness (LWR), an LCDU, a hole LCDU, a circle edge roughness (CER) an edge placement error (EPE), or a combination thereof.

In an embodiment, the design variables may comprise an ILS (e.g., more specifically a blurred ILS (ILSB)), dose and image intensity (e.g., aerial image intensity). The blurred ILS (ILSB) is the image log slope ILS (or normalized ILS) having a spatial blur applied thereto (e.g., by convolution with a Gaussian distribution), such that a blurred ILS has less contrast/slope than the unblurred aerial image. The spatial blur may represent blur of a resist image due to diffusion of a chemical species generated in a resist layer by exposure to radiation.

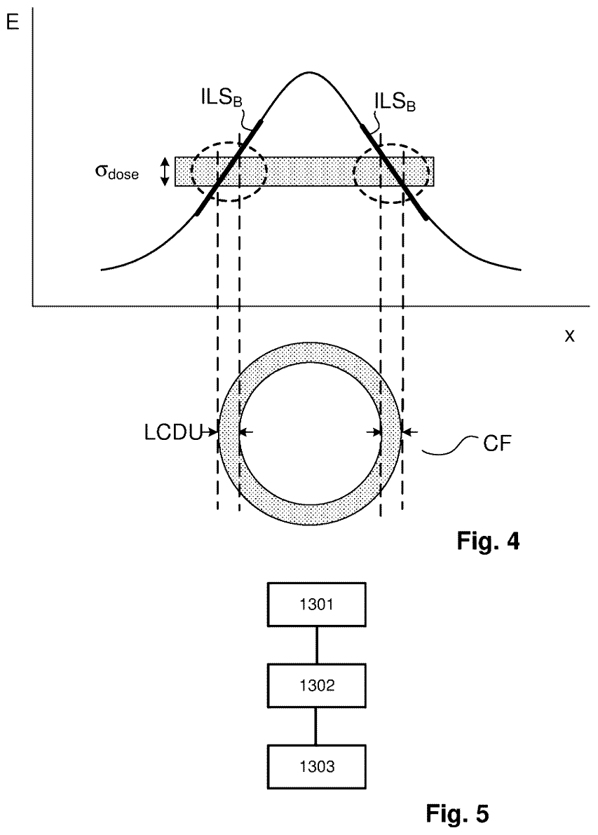

FIG. 4 illustrates how a blurred ILS ILSB can be used to translate local dose variations into local CD (or other stochastic parameter) variations. It shows a plot of dose E against position x, the curve representing the absorbed dose within the resist. Due to the limited number of photons, the absorbed dose obeys Poissonian statistics, resulting in an intrinsic local dose variation σ_{dose}, which in turn results in a variation in the number of photons absorbed by the resist <Nₚₕ>. The blurred ILS ILSB comprises a combination of the ILS defined by the aerial image and this local dose variation σ_{dose}. The blurred ILS ILSB translates the local dose variation σ_{dose} into a resultant local CD variation LCDU, shown here as a CD variation range describing a circular feature CF, although this is equally applicable to any feature. The LCDU (in nm) will depend on the blurred ILS ILSB and the number of photons absorbed by the resist <Nₚₕ> according to:

$$LCDU = \sqrt{\frac{1}{〈 {N}_{ph} 〉}} \frac{1}{{ILS}_{B}}$$

where

$$\sqrt{\frac{1}{〈 {N}_{ph} 〉}}$$

scales with the local dose variation σ_{dose}.

FIG. 5 is a flowchart of a method of determining a relationship between a stochastic variation of a characteristic of an aerial image or a resist image and one or more design variables In step 1301, values of the characteristic are measured from a plurality of aerial images or resist images formed (by actual exposure or simulation) for each of a plurality of sets of values of the one or more design variables. In step 1302, a value of the stochastic variation is determined for each set of values of the one or more design variables from a distribution of the values of the characteristic measured from the aerial images or resist images formed for that set of values of the one or more design variables. In step 1303, a relationship is determined by fitting one or more parameters of a model from the values of the stochastic variation and the sets of values of the one or more design variables.

In an example, the stochastic variation is the LER and the one or more design variables are blurred image ILS ILSB, dose E and image intensity I. The model may be:

$$LER = a \times {ILS}_{B}^{b} \times {( E \times I )}^{c}$$

where the parameters a, b and c may be determined by fitting. The blurred image ILS ILSB is the image log slope ILS with a spatial blur applied thereto. The spatial blur may represent blur of a resist image due to diffusion of a chemical species generated in a resist layer by exposure to radiation.

Once the relationship between a stochastic variation of a characteristic of an aerial image or a resist image and one or more design variables is determined, a value of the stochastic variation may be calculated for that characteristic using the relationship.

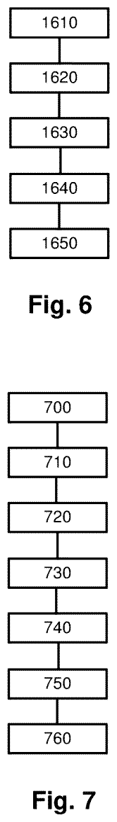

FIG. 6 shows an exemplary flow chart for this calculation. In step 1610, a set of conditions (e.g., NA, s, dose, focus, resist chemistry, one or more projection optics parameters, one or more illumination parameters, etc.) are selected. In step 1620, the values of the one or more design variables are calculated under these conditions. For example, values of edge position of a resist image and blurred ILS along the edges. In step 1630, values of the stochastic variation are calculated from the relationship between the stochastic variation and the one or more design variables. For example, in an example, the stochastic variation is the LER of the edges. In optional step 1640, a noise vector may be defined, whose frequency distribution approximately matches real substrate measurements. In optional step 1650, the noise vector is overlaid on the results (e.g., stochastic edge of the aerial image or resist image).

The relationship between a stochastic variation of a characteristic of an aerial image or a resist image and one or more design variables may also be used to identify one or more “hot spots” or critical features of the aerial image or resist image. A “hot spot” can be defined as a location on the image where the stochastic variation is beyond a certain magnitude. For example, if two positions on two nearby edges have large values of LER, these two positions have a high chance of joining each other.

In an example, values of a stochastic variation (and/or a function thereof) at a plurality of conditions and at a plurality of values of the one or more design variables may be calculated and compiled in a non-transitory computer-readable medium, such as a database stored on a hard drive. A computer may query the medium and calculate a value of the stochastic variation from the content of the medium.

Determination of a stochastic variation of a characteristic of an aerial/resist image may be useful in many ways in the lithographic process. In one example, the stochastic variation may be taken into account in optical proximity correction (OPC).

As an example, OPC addresses the fact that the final size and placement of an image of the design layout projected on the substrate will not be identical to, or simply depend only on the size and placement of, the design layout on the patterning device. It is noted that the terms “mask”, “reticle”, “patterning device” are utilized interchangeably herein. Also, person skilled in the art will recognize that, especially in the context of lithography simulation/optimization, the term “mask”/“patterning device” and “design layout” can be used interchangeably, as in lithography simulation/optimization, a physical patterning device is not necessarily used but a design layout can be used to represent a physical patterning device. For the small feature sizes and high feature densities present on some design layouts, the position of a particular edge of a given feature will be influenced to a certain extent by the presence or absence of other adjacent features. These proximity effects arise from minute amounts of radiation coupled from one feature to another and/or non-geometrical optical effects such as diffraction and interference. Similarly, proximity effects may arise from diffusion and other chemical effects during, e.g., post-exposure bake (PEB), resist development, and etching that generally follow lithography.

For irregular or non-repetitive patterns, such as those of logic structures, there are many different features present. In such a case, lithography performance will vary from one feature to another because of variation in optical proximity caused by different local mask transmittance (LMT).

Therefore, due to the number and variety of different features present in such patterns, metrology used to characterize the lithography performance of such features should cover an extensive measurement area in order to inspect a sufficient variety of features. Ideally, a full characterization of lithography performance would require SEM measurement of the full area containing all features. However, this is prohibitively expensive in terms of time.

An alternative approach to measuring a large area, is to focus on a handful of clips or hotspots and monitoring, e.g. through pitch. This can cover some of the range of features within the logic design. However, hotspots are normally not clustered in small area, so a single or a limited number of SEM images using a limited field of view (FOV) will not capture all the variety, even in only the hotspots. These hotspots are likely to have quite different lithography performance.

The size of the FOV of an SEM sets the size of the pattern area that is imaged and therefore how many individual features are captured and measured. Which individual features are captured is further dependent on the position of the FOV with respect to the pattern.

Presently, a sub-area of the exposed pattern (i.e., a die pattern) is measured using an SEM and used to compute performance of all mask features. Grouping methods may be used which group features into groups with similar lithography performance, such that only a subset of each group needs to be measured, it being assumed that all features of a group behaves the same.

Since the pattern is not uniform, the choice of the SEM's FOV or set of FOVs is important. The FOV(s) will determine how accurately the imaging performance of the unique features can be computed from the metrology data obtained in the measurement. Therefore, it is desirable to determine an optimal FOV (or set of FOVs) before any measurement is performed. Note that, while in some embodiments a method for configuring a single FOV will be determined, the concepts disclosed herein may be used to determine a set of FOVs (e.g., each FOV covering a respective different area of the pattern), e.g., provided the set of FOVs can be captured within an acceptable time or allocated metrology budget.

In addition, it may be that multiple performance metrics or parameters of interest, such as for example CD and placement error (PE)/edge placement error (EPE), are computed from the measurements. These multiple parameters of interest may also be computed for different feature orientations. Each of these parameters of interest might have different optimal FOV; however measuring a different FOV per parameter of interest is also not desirable.

As such, a method is proposed for configuring a Field Of View (FOV) configuration of an inspection apparatus with respect to a patterned substrate to be measured, the method comprising: obtaining at least one parameter of interest distribution across at least a portion of the patterned substrate; determining a variation metric quantifying an amount of variation captured within the parameter distribution when limited to the FOV for varied FOV configurations; and configuring the FOV configuration with respect to the pattern based on said variation metric.

The FOV configuration may describe a size and/or position of an FOV or set of FOVs.

The at least one parameter of interest distribution may comprise a plurality of parameter of interest distributions, each relating to a different respective parameter of interest such that the FOV or set of FOVs is optimized for or across a number of different parameters of interest.

The FOV configuration method may be based on an “optimal design” objective which maximizes the information obtained from a design of experiment. In the design of experiments, optimal designs are a class of experimental designs that are optimal with respect to some statistical criterion. In the design of experiments for estimating statistical models, optimal designs allow parameters to be estimated without bias and with minimum variance. A non-optimal design requires a greater number of experimental runs to estimate the parameters with the same precision as an optimal design. In practical terms, optimal experiments can reduce the costs of experimentation. The optimality of a design depends on the statistical model and is assessed with respect to a statistical criterion, e.g., which is related to the variance-matrix of the estimator.

Maximizing the information obtained from a design of experiment is equivalent to minimizing the expected variance of the statistical model that is used to estimate parameters of interest from the experiment (measurement). The optimal design depends on the class of the statistical model. The method proposed herein may assume a linear estimator for parameters of interest. This covers a wide range of models without the need to design for a specific model choice.

In an embodiment, the measurement for which the FOV (or set of complementary FOVs) is being optimized may be used to estimate a parameter of interest of heterogeneous layout features, or to jointly estimate a plurality of parameters of interest of heterogeneous layout features. Example of such parameters of interest may comprise one or more imaging parameters such as one or more of CD, PE, LCDU and/or LPE in horizontal and/or vertical directions/orientations.

FIG. 7 is a flowchart describing a method of configuring an FOV or set of FOVs according to an embodiment. At step 700, the method may begin by obtaining metrology data from which feature-to-feature covariances of the parameters of interest may be estimated. The data can be either simulated metrology data, measured metrology data or a combination of both. The metrology data may comprise data of one or more parameters of interest, e.g., the metrology data may describe different parameters of interest for each of the features.

Using simulated metrology data prior to performance of any measurement may be the most practical implementation. Where simulated metrology data is used, it may be obtained by simulating the parameters of interest using a lithography simulation. The simulation may be performed for varied imaging conditions, e.g., over an expected range as might be encountered in an actual lithographic process. The imaging conditions varied may be, for example focus and/or dose. When a parameter of interest cannot be directly simulated, another image parameter with a theoretical correlation to the parameter of interest may be used as a proxy. For example instead of LCDU, image-log slope ILS may be used in its place. More generally, a full 3D photoresist aerial image may be simulated, which can be used as a proxy parameter that correlates with all parameters of interest.

Other simulated metrology data which might be used (as an alternative or in addition to the other data types discussed herein) may comprise mask aerial image measurement (AIMS) data. AIMS data may simulate an aerial image generated via the mask (as described in the LMT data or layout data or any suitable description of the pattern, e.g., as can be determined from a.gds file) using a particular lithography tool (scanner) and particular scanner settings indicative of the actual tool and setting which are to be used. AIMS is described in the publication: A. M. Zibold et al, “Aerial Image Measurement Technique for Today's and Future 193 nm Lithography Mask Requirements”; 10.1117/12.568016; Proceedings of SPIE (incorporated herein by reference).

In an alternative or in addition to the other data types discussed herein, the metrology data may be measured metrology data. e.g., from SEM measurement of an exposed wafer, having had the pattern exposed thereon. In this case, the parameter(s) of interest for all or subset of features may be measured during a setup phase with extensive measurement.

At step 710, a metrology data matrix X is constructed. This metrology data matrix may describe the simulated/measured parameters (columns) per layout coordinate (rows). The layout-coordinate may correspond to a specific section of the edge of the polygon (layout feature) to which the parameters belong.

At step 720, a dimensionality reduction step may be performed. This may comprise, for example, calculating a singular value decomposition (X=USV^{T}) of the simulated parameters matrix. The first few left singular vectors corresponding to largest singular values are retained for the subsequent steps. These first few left singular vectors may be described by a matrix Uₖ which consists of the first k columns of the matrix U, where k may be any number less than 20, or any number less than 10 for example.

At step 730, for a given FOV size (or given multiple FOV sizes, i.e., the given FOV size may relate to non-contiguous windows), an exhaustive search for all possible FOVs (candidate FOVs) and locations may be performed. This may be achieved, for example, by scanning a sliding window over the pattern or relevant unit cell of the layout. The features which are captured in each window may be recorded. For example, a set of indices of features which fall in i-th window may be described as rᵢ.

At step 740, for each window, a optimality criterion may be calculated; e.g., using the sub-matrix U_{ri,k} consisting of rows rᵢ which correspond to features in the window and first k columns of matrix U (where no dimensionality reduction is performed the matrix Xᵣᵢ may be used instead). Depending on the objective, different optimality criterion may be used based on a determination of a variation metric. Examples of different optimality criteria include:
A-optimal criterion:

$${m}_{A} ( i ) = tr [ {( {U}_{{r}_{i} k}^{T} {U}_{{r}_{i} , k} )}^{- 1} ] . {m}_{A} ( i )$$

is a measure of the expected total variance of the error of a linear estimator trained on measurement of i-th window.
E-optimal criterion:

$${m}_{E} ( i ) = \frac{1}{{σ}_{min} ( {U}_{{r}_{i} , k} )} ,$$

where σₘᵢₙ (U_{ri,k}) is the smallest singular value of matrix U_{ri,k}. m_{E} (i) is a measure of the expected variance of the error of the worst parameter or worst case of a linear estimator trained on measurement of i-th window. Note that the worst case is not necessarily one of the parameters of interest e.g., the parameter having a highest associated error. It can also, for example, be a linear combination of such parameters having the highest associated error.

At step 750, steps 730 and 740 can be repeated for different FOV sizes to establish a trade-off between size of FOV (related to the cost of measurement) and optimality metric (benefit).

At step 760, the window with minimum variation metric, e.g., minimum m_{A} (i) or m_{E} (i), is chosen as the optimal FOV for measurement.

Further embodiments of the invention are disclosed in the list of numbered clauses below:
1. A method for configuring a field of view configuration of an inspection apparatus with respect to a pattern on a patterned substrate to be measured, the method comprising: obtaining metrology data comprising at least one parameter distribution across at least a portion of the pattern, said at least one parameter distribution relating to a respective one or more parameters of interest and/or respective one or more proxy parameters for a parameter of interest; determining variation metric data from the metrology data, the variation metric data quantifying an amount of variation captured within the parameter distribution when limited to a field of view, for varied field of view configurations; and configuring the field of view configuration with respect to the pattern based on said variation metric data.
2. A method according to clause 1, wherein said field of view configuration describes a size and/or position of a field of view or respective sizes and/or positions of a set of complementary fields of view.
3. A method according to clause 1 or 2, wherein the at least one parameter distribution comprise a plurality of parameter distributions, each relating to a different respective parameter of interest or proxy parameter such that the field of view configurations are configured for a number of different parameters.
4. A method according to any preceding clause, wherein said one or more parameters of interest comprises one or more of critical dimension, placement error, edge placement error, line placement error, and/or Local CD Uniformity in one or two perpendicular orientations of a substrate plane.
5. A method according to any preceding clause, wherein the one or more proxy parameters comprises a simulated photoresist aerial image and/or an image log slope.
6. A method according to any preceding clause, wherein said metrology data comprises simulated metrology data.
7. A method according to clause 6, comprising performing an initial simulation step to obtain said simulated metrology data.
8. A method according to clause 7, comprising performing said simulation step for various imaging conditions.
9. A method according to clause 8, wherein said imaging conditions may comprise focus and/or dose.
10. A method according to any preceding clause, wherein said metrology data comprises measured metrology data from a previously exposed substrate having had said pattern exposed thereon.
11. A method according to any preceding clause, wherein said pattern comprises a plurality of different features.
12. A method according to any preceding clause, wherein said configuring step comprises configuring the field of view configuration so as to minimize an expected variance, described by the variation metric data, of a statistical model used to estimate said at least one parameter of interest and/or at least one proxy parameters from the metrology data.
13. A method according to any preceding clause, comprising: defining a field of view size; performing a search of candidate fields of view over said pattern, each candidate field of view having said field of view size; and determining an optimality criterion for each said candidate field of view, said optimality criterion being based on said variation metric.
14. A method according to clause 13, wherein said step of performing a search comprises: scanning a sliding window defined by said field of view size over a unit cell of the pattern; and determining the features within each window.
15. A method according to clause 13 or 14, wherein said optimality criterion comprises an A-optimality criterion.
16. A method according to clause 15, wherein said variation metric is a measure of the expected total variance of the error of a linear estimator trained on a measurement defined by each candidate field of view.
17. A method according to clause 13 or 14, wherein said optimality criterion comprises an E-optimality criterion.
18. A method according to clause 17, wherein said variation metric is a measure of the expected variance of the error of the worst parameter or combination of parameters of a linear estimator trained on a measurement defined by each candidate field of view.
19. A method according to any preceding clause, comprising performing an initial dimensionality reduction on said metrology data.
20. A method according to clause 19, wherein said dimensionality reduction comprises a singular value decomposition, wherein a first one or more left singular vectors corresponding to largest singular values are used in place of the metrology data for the steps of determining a variation metric and configuring an field of view configuration.
21. A method according to any preceding clause, wherein said inspection apparatus comprises an electron microscope.
22. A method according to any preceding clause, comprising performing metrology on a substrate using said field of view configuration.
23. A computing apparatus comprising a processor, and being configured to perform the method of any preceding clause.
24. An inspection apparatus being operable to image one or more features on a substrate, and comprising the computing apparatus of clause 23.
25. An inspection apparatus according to clause 24, wherein the inspection apparatus is an electron microscopy inspection apparatus.
26. An inspection apparatus according to clause 24, wherein the inspection apparatus is a scanning electron microscopy inspection apparatus or transmission electron microscopy inspection apparatus.
27. A computer program comprising program instructions operable to perform the method of any of clauses 1 to 21, when run on a suitable apparatus.
28. A non-transient computer program carrier comprising the computer program of clause 27.

While the concept is disclosed in terms of a scanning electron microscope (SEM), which includes an e-beam metrology/inspection tool, it also applies to any other metrology or inspection device which has a configurable FOV in terms of size and/or position with respect to the pattern being measured. For example the metrology/inspection device may be any other electron microscope such as a transmission electron microscope (TEM).

The terms “radiation” and “beam” used in relation to the lithographic apparatus encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A method for configuring a field of view configuration of an inspection apparatus with respect to a pattern on a patterned substrate to be measured, the method comprising:
obtaining metrology data comprising at least one parameter distribution across at least a portion of the pattern, the at least one parameter distribution relating to a respective one or more parameters of interest and/or respective one or more proxy parameters for a parameter of interest;
determining variation metric data from the metrology data, the variation metric data quantifying an amount of variation captured within the parameter distribution when limited to a field of view, for varied field of view configurations; and
configuring the field of view configuration with respect to the pattern based on the variation metric data.

2. The method as claimed in claim 1, wherein the field of view configuration describes a size and/or position of a field of view or respective sizes and/or positions of a set of complementary fields of view.

3. The method as claimed in claim 1, wherein the at least one parameter distribution comprises a plurality of parameter distributions, each relating to a different respective parameter of interest or proxy parameter such that the field of view configurations are configured for a number of different parameters.

4. The method as claimed in claim 1, wherein the one or more parameters of interest or the parameter of interest comprises one or more selected from: critical dimension (CD), placement error, edge placement error, line placement error, and/or local CD uniformity in one or two perpendicular orientations of a substrate plane.

5. The method as claimed in claim 1, wherein the at least one parameter distribution relates to a respective one or more proxy parameters for a parameter of interest and wherein the one or more proxy parameters comprises a simulated photoresist aerial image and/or an image log slope.

6. The method as claimed in claim 1, wherein the metrology data comprises simulated metrology data.

7. The method as claimed in claim 6, further comprising performing an initial simulation to obtain the simulated metrology data.

8. The method as claimed in claim 1, wherein the metrology data comprises measured metrology data from a previously exposed substrate having had the pattern exposed thereon.

9. The method as claimed in claim 1, wherein the pattern comprises a plurality of different features.

10. The method as claimed in claim 1, wherein the configuring comprises configuring the field of view configuration so as to minimize an expected variance, described by the variation metric, of a statistical model used to estimate the at least one parameter of interest and/or at least one proxy parameter from the metrology data.

11. The method as claimed in claim 1, further comprising:
defining a field of view size;
performing a search of candidate fields of view with respect to the pattern, each candidate field of view having the field of view size; and
determining an optimality criterion for each candidate field of view, the optimality criterion being based on the variation metric.

12. The method as claimed in claim 11, wherein the step of performing a search comprises:
scanning a sliding window defined by the field of view size over a unit cell of the pattern; and
determining the features within each window.

13. The method as claimed in claim 1, further comprising performing an initial dimensionality reduction on the metrology data.

14. (canceled)

15. A non-transient computer program carrier comprising a computer program therein, the computer program, when executed by one or more processors, configured to cause the one or more processors to at least:
obtain metrology data comprising at least one parameter distribution across at least a portion of a pattern on a patterned substrate to be measured, the at least one parameter distribution relating to a respective one or more parameters of interest and/or respective one or more proxy parameters for a parameter of interest:
determining variation metric data from the metrology data, the variation metric data quantifying an amount of variation captured within the parameter distribution when limited to a field of view of an inspection apparatus, for varied field of view configurations; and
configuring the field of view configuration with respect to the pattern based on the variation metric data.

16. The carrier as claimed in claim 15, wherein the field of view configuration describes a size and/or position of a field of view or respective sizes and/or positions of a set of complementary fields of view.

17. The carrier as claimed in claim 15, wherein the at least one parameter distribution comprises a plurality of parameter distributions, each relating to a different respective parameter of interest or proxy parameter such that the field of view configurations are configured for a number of different parameters.

18. The carrier as claimed in claim 15, wherein the one or more parameters of interest or the parameter of interest comprises one or more selected from: critical dimension (CD), placement error, edge placement error, line placement error, and/or local CD uniformity in one or two perpendicular orientations of a substrate plane.

19. The carrier as claimed in claim 15, wherein the at least one parameter distribution relates to a respective one or more proxy parameters for a parameter of interest and wherein the one or more proxy parameters comprises a simulated photoresist aerial image and/or an image log slope.

20. The carrier as claimed in claim 15, wherein the metrology data comprises simulated metrology data.

21. The carrier as claimed in claim 15, wherein the computer program configured to cause the one or more processors to configure the field of view configuration is configured to cause the one or more processors to configure the field of view configuration so as to minimize an expected variance, described by the variation metric, of a statistical model used to estimate the at least one parameter of interest and/or at least one proxy parameter from the metrology data.
